(19) United States
(12) Patent Application Publication
(10) Pub. No.: US 2026/0177321 A1
(43) Pub. Date: Jun. 25, 2026

(54) JIG FOR EXHAUST STRUCTURE WORK OF CHAMBER

(71) Applicant: HPSP Co., Ltd., Hwaseong-si (KR)

(72) Inventor: Dave POWELL, Sunnyvale, CA (US)

(21) Appl. No.: 19/413,459

(22) Filed: Dec. 9, 2025

Related U.S. Application Data
(60) Provisional application No. 63/738,210, filed on Dec. 23, 2024.

(51) Int. Cl. F27D 17/30; F23J 13/04; H10P 72/00

(52) U.S. Cl. CPC F27D 17/302; F23J 13/04; H10P 72/0402

(57) ABSTRACT

A jig for exhaust structure work of a chamber is disclosed. The jig includes a base, a support, and a centering unit. The base may be formed to be disposed with respect to the exhaust socket of the chamber. The support may extend upward from the base to support an exhaust connector connected to the exhaust socket. The centering unit may be connected to the base and formed to center the base with respect to the exhaust socket based on a through hole of the chamber through which the exhaust socket passes.

### BACKGROUND

### 1. Field

The present invention relates to a jig for exhaust structure work of a chamber.

### 2. Description of Related Art

Generally, in a semiconductor device manufacturing process, a substrate processing device performs various processes on a semiconductor substrate. Examples of the processing include oxidation, nitridation, ion implantation, deposition processes, etc. A hydrogen or deuterium heat treatment process is also used to improve the interface characteristics of the semiconductor device.

The reaction gas used for this process is supplied to the chamber of the substrate processing device and acts on the semiconductor substrate. The reaction gas is exhausted from the chamber after acting on the semiconductor substrate. Reference may be made to U.S. patent application Ser. No. 19/036,567 (filed on Jan. 24, 2025) by the present applicant for such a substrate processing device. Referring to FIG. 2 of the application, an upper end portion (exhaust socket) of an inner chamber 110 is connected to a gas exhaust line 141 of an exhaust module 140.

The specific connection between the exhaust socket and the gas exhaust line 141 will be described with reference to FIG. 1. FIG. 1 is a perspective view illustrating an exhaust structure of a chamber in a substrate processing device.

Referring to this drawing, an exhaust socket S passes through a through hole (O) in the cooling plate C and protrudes upward from the cooling plate C.

The exhaust socket S communicates with an exhaust pipe EP via an exhaust connector J. Two cooling water pipes WP₁ and WP₂ may communicate with a body of the exhaust connector J. The cooling water pipes WP₁ and WP₂ allow cooling water to circulate within the body of the exhaust connector J to protect the exhaust connector J from the heat of high-temperature exhaust gas flowing from the exhaust socket S to the exhaust pipe EP. Here, the exhaust connector J (and the clamp plate CP to be described below) and the exhaust pipe EP are referred to as the gas exhaust line, and the gas exhaust line and the exhaust socket S may be referred to as the exhaust structure.

The exhaust connector J has a lower plate LP, which may be bolted to the clamp plate CP. The lower plate LP and the clamp plate CP are engaged with the ball portion (B, see FIG. 2) of the exhaust socket S, so the exhaust connector J is fixed to the exhaust socket S.

### SUMMARY

According to the present inventor's understanding, while connecting the cooling water line to the exhaust connector, stress is applied to the exhaust connector from the two cooling water lines, and this stress may be transferred to the exhaust socket supporting the exhaust connector. In this case, the exhaust socket, made of fragile quartz, may be damaged, so this process should be performed with extreme care. When the exhaust socket is damaged, the entire internal chamber should be replaced, resulting in significant waste. Even if the exhaust socket is not damaged, when the exhaust socket and exhaust connector are not connected in a precise alignment, the reaction gas may leak from the connection.

The present invention has been made in view of the above-described problems, and an object of the present invention is to provide a jig for exhaust structure work of a chamber capable of contributing to preventing stress on the exhaust socket during the process of connecting a gas exhaust line to the exhaust socket.

Another object of the present invention is to provide a jig for exhaust structure work of a chamber capable of contributing to ensuring precise alignment between connected components during the process of connecting a gas exhaust line to the exhaust socket.

However, problems to be solved by the present invention are not limited to the above-mentioned aspects. That is, other aspects that are not described may be obviously understood by those skilled in the art from the following specification.

According to an aspect of the present invention, a jig for exhaust structure work of a chamber includes: a base formed to be disposed with respect to an exhaust socket of the chamber; a support extending upward from the base to support an exhaust connector connected to the exhaust socket; and a centering unit connected to the base and formed to center the base with respect to the exhaust socket.

The base may be formed with an open accommodating slot for accommodating the exhaust socket.

An inner circumferential surface of the accommodating slot may be formed to be spaced apart from an outer circumferential surface of the exhaust socket while the base is centered with respect to the exhaust socket.

The base may be formed with a seating groove for seating a clamp plate coupled with the exhaust connector with respect to the exhaust socket.

The support may include a pair of vertical bars perpendicular to the base, and the pair of vertical bars may be formed so that they are respectively on opposite sides of the exhaust socket.

The centering unit may be formed so as to be insertable into a through hole of the chamber through which the exhaust socket passes.

The centering unit may include a pair of movable members connected to the base so as to be movable toward or away from each other.

The movable member may include a pivotal plate pivotally connected to the base.

Each of the pair of movable members may include a first stopping part, and the pair of first stopping parts may be positioned so as to correspond to each other and are formed to stop the pair of movable members at a position spaced apart from an outer circumferential surface of the exhaust socket while moving in a direction in which inner circumferential surfaces of the pair of movable members move closer to each other.

Each of the pair of movable members may further include a second stopping part, the pair of second stopping parts may be positioned so as to correspond to each other and may be formed to stop the pair of movable members while moving in a direction in which the inner circumferential surfaces of the pair of movable members move away from each other, and the first stopping part and the second stopping part may be arranged in different directions.

The movable member may include: a contact outer circumferential surface formed to contact an inner circumferential surface of the through hole while the centering unit is inserted into the through hole; and a separation inner circumferential surface formed to be spaced apart from an outer circumferential surface of the exhaust socket while the centering unit is inserted into the through hole.

The centering unit may include a fixed member fixedly connected to the base, and the fixed member may include: a contact outer circumferential surface formed to contact an inner circumferential surface of the through hole while the centering unit is inserted into the through hole; and a separation inner circumferential surface formed to be spaced apart from an outer circumferential surface of the exhaust socket while the centering unit is inserted into the through hole, and the separation inner circumferential surface may be formed to be open to accommodate the exhaust socket.

The centering unit may include: a body formed to be inserted into the through hole; and an elastic contact member installed in the body and elastically contacting an inner circumferential surface of the through hole.

The elastic contact member may include a ball plunger.

The centering unit may be detachably connected to the base.

The jig may further include: a fastening structure formed to fasten the support to the exhaust connector.

The fastening structure may include a screw hole formed at an upper end of the support for screw engagement with a fastening slot of the exhaust connector.

The support may be detachably coupled to the base.

According to another aspect of the present invention, a jig for exhaust structure work of a chamber includes: a base having a supporting plate formed to be positioned in relation to an exhaust socket of a chamber; a support extending upward from the supporting plate to support an exhaust connector connected to the exhaust socket; and a centering unit connected to the supporting plate, formed to be inserted into a through hole of the chamber through which the exhaust socket passes, and formed to center the supporting plate with respect to the exhaust socket, in which the base further includes a seating groove formed in the supporting plate to correspond to a contour of a clamp plate coupled with the exhaust connector with respect to the exhaust socket.

The centering unit may include a pair of pivotal plates connected to the base so as to be pivotally movable toward or away from each other.

### BRIEF DESCRIPTION OF DRAWINGS

FIG. 1 is a perspective view illustrating an exhaust structure of a chamber in a substrate processing device.

FIG. 2 is a perspective view illustrating a state in which a jig according to an embodiment of the present invention is used for working on an exhaust structure of a chamber.

FIG. 3 is a perspective view of the jig of FIG. 2 when viewed from the top.

FIG. 4 is a perspective view of the jig of FIG. 3, viewed upside down.

FIG. 5 is a plan view illustrating the centering unit of FIG. 4 centered with respect to a through hole.

FIG. 6 is a perspective view illustrating the centering unit of a jig according to another embodiment of the present invention centered with respect to a through hole.

FIG. 7 is a perspective view illustrating a centering unit according to a modified example of the centering unit of FIG. 6.

FIG. 8 is a plan view illustrating a state in which the jig is centered according to another embodiment of the present invention.

FIG. 9 is a perspective view illustrating a base of the jig according to still another embodiment of the present invention.

FIG. 10 is a perspective view showing another state in which the base of FIG. 9 is used for work on the exhaust structure of the chamber.

### DETAILED DESCRIPTION

Hereinafter, exemplary embodiments of the present invention will be described in detail with reference to the accompanying drawings.

The present invention is not limited to exemplary embodiments set forth herein, but may be modified in various different forms. However, the present embodiment is provided solely to ensure that the disclosure of the present invention is complete and to fully inform those skilled in the art of the scope of the invention. It should be understood that the accompanying drawings are provided only in order to allow embodiments disclosed in the present specification to be easily understood, and are not intended to limit the teachings disclosed in the present specification. All the modifications, equivalents, and substitutions may be made without departing from the teachings and the scope of the present invention.

It should be understood that the accompanying drawings are provided only in order to allow embodiments disclosed in the present specification to be easily understood, and the teachings disclosed in the present specification are not limited by the accompanying drawings, but includes all the modifications, equivalents, and substitutions included in the teachings and the scope of the present invention. In the drawings, components may be exaggerated in size or thickness for ease of understanding, but this should not be construed as limiting the scope of protection of the present invention.

Terms used in the present specification are used only in order to describe specific implementation examples or embodiments rather than limiting the present invention. Singular expressions are intended to include plural expressions unless the context clearly indicates otherwise. In the specification, terms such as “˜comprising,” or “˜consisting of” are intended to specify the presence of stated features, numbers, steps, operations, components, parts, or combinations thereof described in the specification. That is, it should be understood that terms such as “˜including” or “˜consisting of” in the specification do not preclude the existence or addition possibility of one or more other features or numbers, steps, operations, components, parts, or combinations thereof.

Terms including ordinal numbers such as “first”, “second”, etc., may be used to describe various components, but the components are not to be construed as being limited to the terms. The terms are used to distinguish one component from another component.

It is to be understood that when one element is referred to as being “connected to/communicate with” or “coupled to” another element, it may be directly connected to/communicate with another element or be coupled to another element, having the other element intervening therebetween. On the other hand, it should be understood that when one element is referred to as being “directly connected to/communicate with” or “coupled directly to” another element, it may be connected to or coupled to another element without the other element interposed therebetween.

When a component is referred to as being “above” or “below” another component, it should be understood that it is not only positioned directly above that other component, but also that other components may be present in between.

Unless indicated otherwise, it is to be understood that all the terms used in the specification including technical and scientific terms have the same meaning as those that are generally understood by those who skilled in the art. It should be understood that the terms defined by the dictionary are identical with the meanings within the context of the related art, and they should not be ideally or excessively formally defined unless the context clearly dictates otherwise.

In the embodiments, the direction associated with the jig is set with respect to the cooling plate of the chamber. The direction parallel to the cooling plate is defined as a horizontal direction, and a direction perpendicularly penetrating through the cooling plate is defined as a vertical direction.

FIG. 2 is a perspective view illustrating a state in which a jig according to an embodiment of the present invention is used for working on an exhaust structure of a chamber.

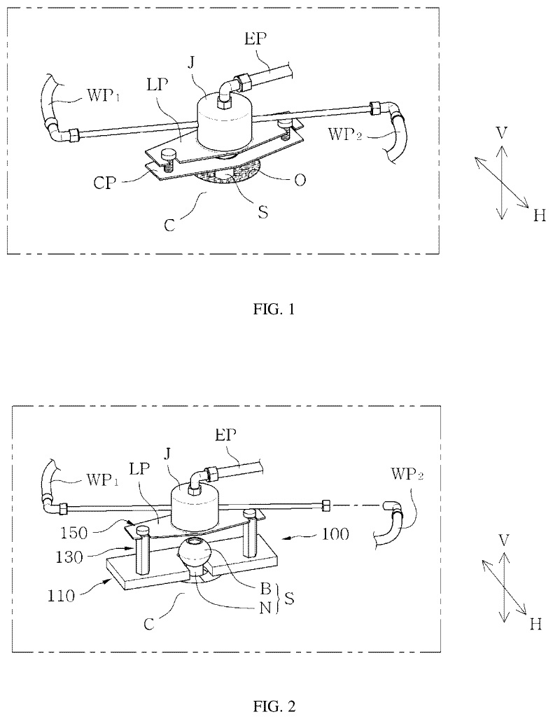

Referring to this drawing (and FIG. 1), an exhaust socket S has a neck portion N and a ball portion B, in which an outer diameter of the ball portion B may be larger than that of the neck portion N. While an operator connects cooling water pipes WP₁ and WP₂ to an exhaust connector J, the jig 100 may support the exhaust connector J, specifically a lower plate LP. This jig 100 may include a base 110, a support 130, and a fastening structure 150.

The base 110 may be a target for installation of a support 130 or the like. The base 110 may be disposed on a cooling plate C adjacent to the exhaust socket S and may be disposed to surround the exhaust socket S.

The support 130 is configured to protrude upward from the base 110 in a vertical direction V. The support 130 may support the lower plate LP and keep an exhaust connector J spaced apart from the exhaust socket S.

The fastening structure 150 is configured to fasten the support 130 to the lower plate LP. The fastening structure 150 may firmly fix the exhaust connector J to the support 130 during operation.

According to this configuration, during operations such as connecting cooling water pipes WP₁ and WP₂ and/or exhaust pipes EP to the exhaust connector J, the jig 100 separates the exhaust connector J in a vertical direction V from the exhaust socket S to prevent the exhaust connector J from applying stress to the exhaust socket S. Even if the cooling water pipes WP₁ and WP₂ apply twisting stress to the exhaust connector J while firmly fastening the cooling water pipes WP₁ and WP₂ to the exhaust connector J, the exhaust connector J still does not apply stress to the exhaust socket S. Accordingly, even if the exhaust socket S is made of a fragile material, the exhaust socket S may be protected from damage during the operation on the exhaust connector J.

The exhaust connector J may be connected to the cooling water pipes WP₁ and WP₂ while aligned with the exhaust socket S. Here, the alignment may include centering, which aligns the center of the exhaust connector J with the center of the exhaust socket S along the horizontal direction H, and leveling, which aligns the exhaust connector J parallel to the cooling plate C. After the exhaust connector J and the cooling water pipes WP₁ and WP₂ are assembled with respect to each other to form an assembly, and the jig 100 is removed, the assembly may descend in the vertical direction V to maintain alignment with the exhaust socket S. This prevents gas leakage within the chamber due to the misalignment of the exhaust connector J with respect to the exhaust socket S.

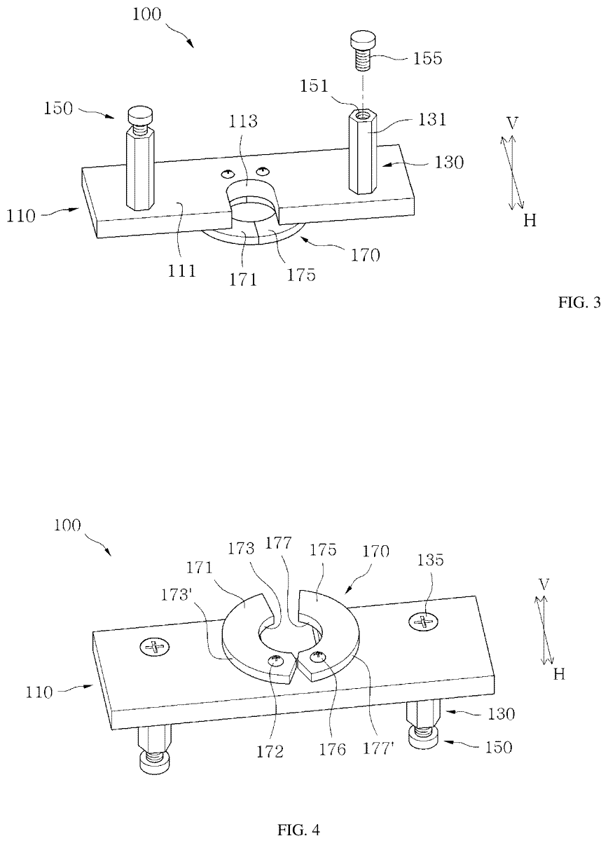

The jig 100 will be described in more detail with reference to FIGS. 3 to 5.

FIG. 3 is a perspective view of the jig of FIG. 2 when viewed from the top.

Referring to this drawing (and FIG. 2), the base 110 may have a generally rectangular supporting plate 111 to be placed on the cooling plate C. An accommodating slot 113 may be formed in the center of the supporting plate 111. The accommodating slot 113 may be open along a horizontal direction H. As the supporting plate 111 slides along the horizontal direction H while placed on the cooling plate C, the accommodating slot 113 may accommodate the neck portion N of the exhaust socket S.

When the supporting plate 111 is centered with respect to the exhaust socket S, an inner circumferential surface of the accommodating slot 113 may be formed to be spaced apart from an outer circumferential surface of the neck portion N. This structure may protect the fragile neck portion N by preventing the supporting plate 111 from applying impact or stress to the neck portion N. In addition, the thickness of the supporting plate 111 along the vertical direction V is smaller than a gap between the cooling plate C and a ball portion B, so that the supporting plate 111 may avoid hitting the ball portion B while approaching the neck portion N along the horizontal direction H.

The support 130 may have a pair of vertical bars 131 perpendicular to the upper surface of the supporting plate 111. The pair of vertical bars 131 may be arranged symmetrically with respect to each other with respect to the accommodating slot 113 along the horizontal direction H.

The fastening structure 150 may be configured to detachably fasten the lower plate LP and the support 130. The fastening structure 150 may be, for example, a screw hole 151 formed on an upper portion of the vertical bar 131. The screw hole 151 corresponds to the fastening slot of the lower plate LP, and a screw 155 may be inserted into the fastening slot and the screw hole 151.

To center the jig 100 with respect to the exhaust socket S, a centering unit 170 may be additionally provided. The centering unit 170 may be connected to the base 110, specifically, to a bottom surface of the supporting plate 111. As the jig 100 is centered with respect to the exhaust socket S, the exhaust connector J supported by the jig 100 may also be centered with respect to the exhaust socket S.

Specifically, the centering unit 170 may be inserted into a recess of the cooling plate C, for example, a through hole O (FIG. 1), so that the jig 100 may be centered with respect to the through hole O. Specifically, the centering unit 170 may be positioned at the centering position as the outer circumferential surface of the centering unit 170 contacts the inner circumferential surface of the through hole O. Furthermore, as the exhaust socket S is positioned at the center of the through hole O, the centering of the jig 100 with respect to the through hole O may lead to centering with respect to the exhaust socket S.

The centering unit 170 may have a pair of movable members 171 and 175. The pair of movable members 171 and 175 may be connected to the supporting plate 111 to move toward or away from each other, specifically, perform translational motion or rotational motion. In the present embodiment, the movable members 171 and 175 may be pivotal plates formed to perform rotational motion, specifically, swing motion, around an axis along the vertical direction V. The pivotal plate is exemplified as having a shape, for example, an arc shape, but is not limited thereto.

According to this configuration, when the centering unit 170 is inserted into the through hole O, the jig 100 may automatically support the exhaust connector J while being centered with respect to the exhaust socket S.

In an alternative embodiment, the support 130 may be a block with a wider upper surface than the vertical bar 131. As the block stably supports the lower plate LP, the fastening between the block and the lower plate LP through the fastening structure 150 may not be necessary.

Furthermore, when a seating groove is formed on the upper surface of the block corresponding to the contour of the lower plate LP and the lower plate LP is seated on the seating groove, the block may more stably support the lower plate LP without fastening to the lower plate LP.

FIG. 4 is a perspective view of the jig of FIG. 3, viewed upside down.

Referring to this drawing (and FIG. 3), the support 130 may be detachably connected to the base 110. For example, the vertical bar 131 may be coupled to the base 110 by a screw 135, a protrusion, etc., and may also be removed from the base 110. The pair of movable members 171 and 175 may also be detachably connected to the base 110 using screws 172 and 176, protrusions, etc. The screws 172 and 176 also serve as axes for the rotational movement of the movable members 171 and 175. With the support 130 and the movable members 171 and 175 removed from the base 110, the base 110 may be used for new types of work (see FIG. 10).

The pair of movable members 171 and 175 may have a separation inner circumferential surface 173 and 177 and a contact outer circumferential surface 173′ and 177′. Both the separation inner circumferential surface 173 and 177 and the contact outer circumferential surface 173′ and 177′ may have an arc shape, but are not limited thereto. For example, the separation inner circumferential surfaces 173 and 177 may have a shape corresponding to a portion of a polygon.

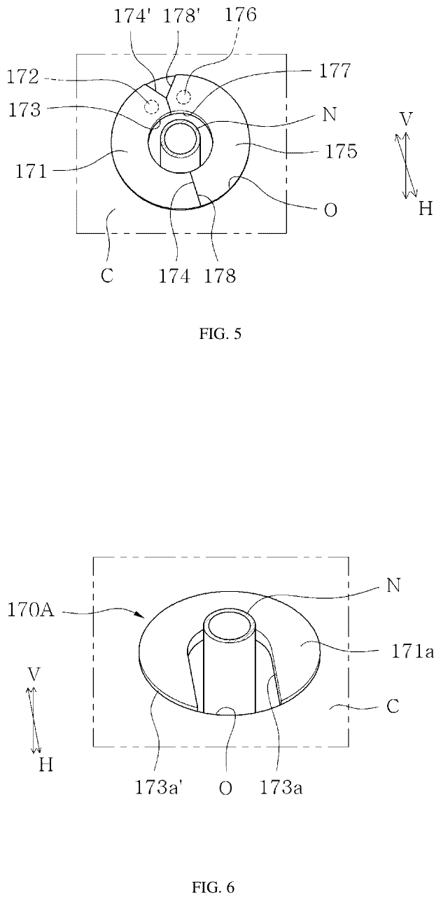

FIG. 5 is a plan view illustrating the centering unit of FIG. 4 centered with respect to a through hole. In the this drawing, for ease of understanding, the exhaust socket S (see FIG. 2) is depicted cut off at the neck portion N. This also applies to FIGS. 6 and 8.

Referring to this drawing (and FIG. 4), the centering unit 170 may approach the neck portion N in the horizontal direction H and then descend in the vertical direction V to be inserted into the through hole O. While inserted into the through hole O, the contact outer circumferential surfaces 173′ and 177′ of the movable members 171 and 175 contact the inner circumferential surface of the through hole O. In contrast, the separation inner circumferential surfaces 173 and 177 may be separated from the exhaust socket S, specifically, the outer circumferential surface of the neck portion N.

Specifically, a pair of movable members 171 and 175 may have first stopping parts 174 and 178. The first stopping parts 174 and 178 may be positioned to correspond to each other so as to stop the pair of movable members 171 and 175 while the separation inner circumferential surfaces 173 and 177 of the pair of movable members 171 and 175 rotate in a direction in which they come closer to each other. As a result, the pair of movable members 171 and 175 may stop the rotational movement at a position spaced apart from the neck portion N. The first stopping parts 174 and 178 may be stopping surfaces formed at both end portions of the pair of movable members 171 and 175 opposite to an end at which screws 172 and 176 are positioned. The stopping surface may be arranged to extend radially from the central axis of the neck portion N.

The pair of movable members 171 and 175 may additionally include second stopping parts 174′ and 178′. The second stopping parts 174′ and 178′ may be stopping surfaces formed at end portions of the pair of movable members 171 and 175 opposite to the end portions where the first stopping parts 174 and 178 are positioned. The second stopping parts 174′ and 178′ may be positioned to correspond to each other. The second stopping parts 174′ and 178′ may stop the pair of movable members 171 and 175 while the separation inner circumferential surfaces 173 and 177 of the pair of movable members 171 and 175 rotate away from each other. The second stopping parts 174′ and 178′ may restrict the rotational movement of the pair of movable members 171 and 175 so that they only open to an angle appropriate for leaving the through hole O and the neck portion N. The stopping surfaces of the first stopping parts 174 and 178 and the second stopping parts 174′ and 178′ may be arranged in different directions.

According to this configuration, when the centering unit 170 is inserted into the through hole O, the contact outer circumferential surface 173′ and 177′ contacts the inner circumferential surface of the through hole O, thereby automatically centering the jig 100 with respect to the exhaust socket S (see FIG. 2). During such a centering process, the separation inner circumferential surfaces 173 and 177 of the pair of movable members 171 and 175 are spaced apart from the neck portion N while being inserted into the through hole O, thereby preventing the neck portion N from being struck. This may protect the fragile neck portion N from being damaged or broken. When the centering unit 170 is removed from the through hole O after the operation, the pair of movable members 171 and 175 may only move apart within a set range, even if they move apart from each other.

FIG. 6 is a perspective view illustrating the centering unit of a jig according to another embodiment of the present invention centered with respect to a through hole.

Referring to this drawing, a centering unit 170A may have a fixed member 171a that is a single member. The fixed member 171a is fixedly connected to the bottom surface of the base 110 (see FIG. 4) and may not move with respect to the base 110.

The fixed member 171a may have an overall disc shape. The disc-shaped outer circumferential surface 173a′ may contact the inner circumferential surface of the through hole O while inserted into the through hole O. Accordingly, the outer circumferential surface 173a′ may be referred to as the contact outer circumferential surface. The jig having the contact outer circumferential surface may be automatically aligned with respect to the neck portion N.

The open slot may be formed in a portion of the fixed member 171a to accommodate the neck portion N. The inner circumferential surface 173a of the open slot may be separated from the neck portion N while the fixed member 171a is inserted into the through hole O. Therefore, the inner circumferential surface 173a does not impact the neck portion N and may be referred to as the separation inner circumferential surface.

The centering unit 170A may also center the jig with respect to the through hole O, like the centering unit 170 (see FIG. 5) according to the above-described embodiment, without impacting the neck portion N. Furthermore, the centering unit 170A does not require the same manipulation (spreading or retracting the pair of movable members 171 and 175) as in the above-described embodiment.

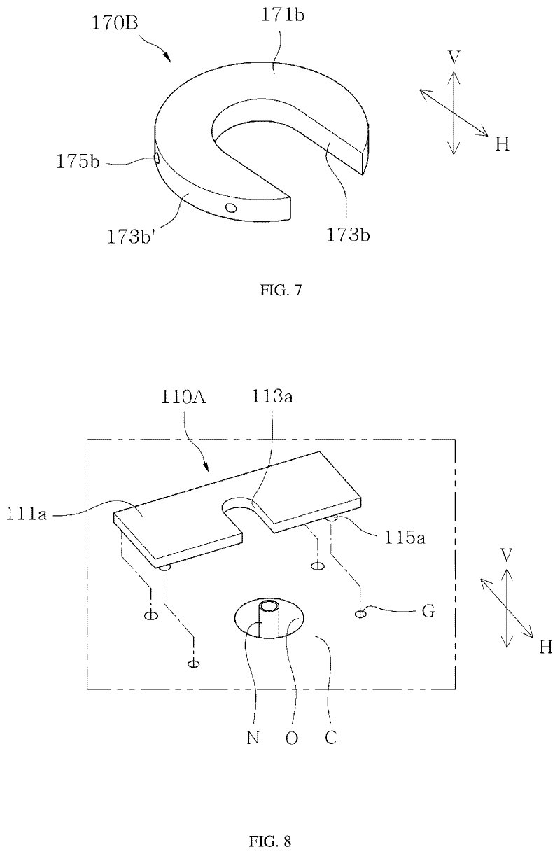

FIG. 7 is a perspective view illustrating a centering unit according to a modified example of the centering unit of FIG. 6.

Referring to this drawing, a centering unit 170B may have a body 171b having a configuration generally similar to the fixed member 171a (see FIG. 6) of the above-described embodiment. An inner circumferential surface 173b of the open slot of the body 171b may be formed to be spaced apart from the neck portion N (see FIG. 6). An outer circumferential surface 173b′ of the body 171b contacts the through hole O, but may have a slight play along the horizontal direction H.

To eliminate even this slight play and achieve more precise centering, the body 171b may be equipped with an elastic contact member 175b. An elastic contact member 175b may be installed on the outer circumferential surface 173b′ of the body 171b to elastically contact the inner circumferential surface of the through hole O. For example, a ball plunger protruding generally radially from the center of the body 171b may be used as the elastic contact member 175b.

With this configuration, as the elastic contact member 175b elastically contacts the inner circumferential surface of the through hole O, the body 171b may be more precisely centered within the through hole O and may firmly maintain the centered state.

According to an alternative embodiment, the elastic contact member 175b may be a spring instead of the ball plunger. The spring may be, for example, a leaf spring, and may be formed to be convex toward the inner surface of the through hole O.

FIG. 8 is a plan view illustrating a state in which the jig is centered according to another embodiment of the present invention.

Referring to this drawing, the centering of the jig may be achieved in a method different from the method of inserting the centering unit into the through hole O in the above-described embodiments.

Specifically, an alignment protrusion 115a may be formed on a supporting plate 111a of a base 110A. The alignment protrusion 115a may protrude from the bottom surface of the supporting plate 111a in the vertical direction V.

The alignment groove G, which is a recessed portion of a different shape, may be formed on the cooling plate C in correspondence to the alignment protrusion 115a. A plurality of alignment grooves G may be formed. The plurality of alignment grooves G may be arranged radially around the through hole O.

With this configuration, the base 110A may approach the neck portion N along the horizontal direction H with the alignment protrusion 115a positioned on the upper surface of the cooling plate C. In this case, the open slot 113a accommodates the neck portion N, thereby preventing the supporting plate 111a from interfering with the neck portion N. When the alignment protrusion 115a is accommodated in the alignment groove G, the base 110A may be centered with respect to the exhaust socket S (see FIG. 2) and furthermore, the through hole O.

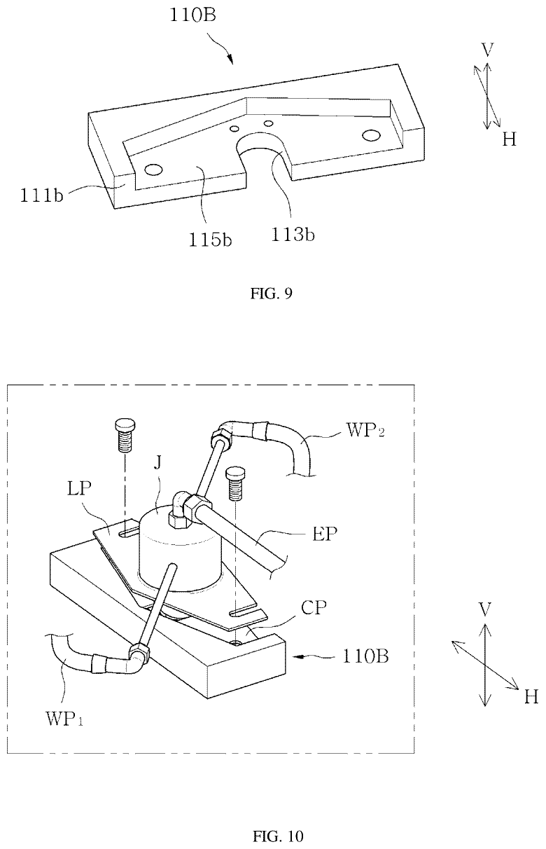

FIG. 9 is a perspective view illustrating a base of the jig according to still another embodiment of the present invention.

Referring to this drawing, the base 110B has a supporting plate 111b and an open slot 113b substantially the same as the base 110 (see FIG. 3) according to the above-described embodiment, but differs in that the base 110B has a seating groove 115b.

The seating groove 115b may be formed to accommodate a clamp plate CP (see FIG. 10). Accordingly, the shape of the inner circumferential surface of the seating groove 115b may be made to correspond to the outer circumferential surface of the clamp plate CP.

FIG. 10 is a perspective view showing another state in which the base of FIG. 9 is used for work on the exhaust structure of the chamber.

Referring to this drawing (and FIG. 9), after connecting the exhaust pipe EP and the cooling water pipes WP₁ and WP₂ to the exhaust connector J, the operator may attempt to connect the clamp plate CP and the lower plate LP using the base 110B. The support 130 and the centering unit 170 (see FIG. 3 above) from the jig 100 may be removed, and only the base 110B may be used for this operation.

The operator may seat the clamp plate CP in the seating groove 115b of the base 110B while the base 110B is positioned at a set point below the lower plate LP by moving the clamp plate CP in the horizontal direction H. The clamp plate CP also moves in the horizontal direction H and is seated in the seating groove 115b, but the clamp plate CP may be moved in the opposite direction from the base 110B. The operator may check the level of the lower plate LP with respect to the clamp plate CP and then screw the lower plate LP to the clamp plate CP.

With this configuration, the clamp plate CP and the lower plate LP may be precisely aligned (specifically, leveled (and centered)) with respect to the exhaust socket S while being fastened to the ball portion B (see FIG. 2) of the exhaust socket S. As a result, the gas leakage from the chamber due to the misalignment between the exhaust socket S and the exhaust connector J (see FIG. 2) may be structurally prevented.

According to the jig for exhaust structure work of a chamber configured as described above, the base, which is disposed on the cooling plate, is configured to protrude upward to support the exhaust connector connected to the chamber's exhaust socket, thereby separating the exhaust connector from the exhaust socket. Therefore, the exhaust connector does not apply stress to the exhaust socket during the process of connecting the gas exhaust line to the exhaust socket. This prevents the waste of having to replace the entire inner chamber due to a break in the exhaust socket.

Furthermore, as the centering unit is configured to center the base with respect to the exhaust socket, the operation of connecting a cooling water pipe or the like to the exhaust connector may contribute to ensuring that the exhaust connector is accurately aligned with the exhaust socket. Consequently, when the exhaust connector that has been completed is connected to the exhaust socket while it is aligned by the centering unit during the operation, it is possible to prevent the exhaust gas leakage caused by the misaligned connection of the exhaust connector to the exhaust socket.

It should be understood that the effects of the present invention are not limited to the above effects, and include all effects that can be inferred from the configuration of the invention described in the detailed description or claims of the present invention.

What is claimed is:

1. A jig for exhaust structure work of a chamber, comprising:
a base formed to be disposed with respect to an exhaust socket of the chamber;
a support extending upward from the base to support an exhaust connector connected to the exhaust socket; and
a centering unit connected to the base and formed to center the base with respect to the exhaust socket.

2. The jig of claim 1, wherein the base is formed with an open accommodating slot for accommodating the exhaust socket.

3. The jig of claim 2, wherein an inner circumferential surface of the accommodating slot is formed to be spaced apart from an outer circumferential surface of the exhaust socket while the base is centered with respect to the exhaust socket.

4. The jig of claim 1, wherein the base is formed with a seating groove for seating a clamp plate coupled with the exhaust connector with respect to the exhaust socket.

5. The jig of claim 1, wherein the support includes a pair of vertical bars perpendicular to the base, and the pair of vertical bars are formed so that they are respectively positioned on opposite sides of the exhaust socket.

6. The jig of claim 1, wherein the centering unit is formed so as to be insertable into a through hole of the chamber through which the exhaust socket passes.

7. The jig of claim 6, wherein the centering unit includes a pair of movable members connected to the base so as to be movable toward or away from each other.

8. The jig of claim 7, wherein the movable member includes a pivotal plate pivotally connected to the base.

9. The jig of claim 7, wherein each of the pair of movable members includes a first stopping part, and
the pair of first stopping parts are positioned so as to correspond to each other and are formed to stop the pair of movable members at a position spaced apart from an outer circumferential surface of the exhaust socket while moving in a direction in which inner circumferential surfaces of the pair of movable members move closer to each other.

10. The jig of claim 9, wherein each of the pair of movable members further includes a second stopping part,
the pair of second stopping parts are positioned so as to correspond to each other and are formed to stop the pair of movable members while moving in a direction in which the inner circumferential surfaces of the pair of movable members move away from each other, and
the first stopping part and the second stopping part are arranged in different directions.

11. The jig of claim 7, wherein the movable member includes:
a contact outer circumferential surface formed to contact an inner circumferential surface of the through hole while the centering unit is inserted into the through hole; and
a separation inner circumferential surface formed to be spaced apart from an outer circumferential surface of the exhaust socket while the centering unit is inserted into the through hole.

12. The jig of claim 1, wherein the centering unit includes a fixed member fixedly connected to the base, and
the fixed member includes:
a contact outer circumferential surface formed to contact an inner circumferential surface of the through hole while the centering unit is inserted into the through hole; and
a separation inner circumferential surface formed to be spaced apart from an outer circumferential surface of the exhaust socket while the centering unit is inserted into the through hole, and
the separation inner circumferential surface is formed to be open to accommodate the exhaust socket.

13. The jig of claim 1, wherein the centering unit includes:
a body formed to be inserted into the through hole; and
an elastic contact member installed in the body and elastically contacting an inner circumferential surface of the through hole.

14. The jig of claim 13, wherein the elastic contact member includes a ball plunger.

15. The jig of claim 1, wherein the centering unit is detachably connected to the base.

16. The jig of claim 1, further comprising:
a fastening structure formed to fasten the support to the exhaust connector.

17. The jig of claim 16, wherein the fastening structure includes a screw hole formed at an upper end of the support for screw engagement with a fastening slot of the exhaust connector.

18. The jig of claim 1, wherein the support is detachably coupled to the base.

19. A jig for exhaust structure work of a chamber, comprising:
a base having a supporting plate formed to be positioned with respect to an exhaust socket of a chamber;
a support extending upward from the supporting plate to support an exhaust connector connected to the exhaust socket; and
a centering unit connected to the supporting plate, formed to be inserted into a through hole of the chamber through which the exhaust socket passes, and formed to center the supporting plate with respect to the exhaust socket,
wherein the base further includes a seating groove formed in the supporting plate to correspond to a contour of a clamp plate coupled with the exhaust connector with respect to the exhaust socket.

20. The jig of claim 19, wherein the centering unit includes a pair of pivotal plates connected to the base so as to be pivotally movable toward or away from each other.
